(19) United States
(12) Patent Application Publication
(10) Pub. No.: US 2013/0134387 A1
(43) Pub. Date: May 30, 2013

(54) SEMICONDUCTOR LIGHT EMITTING ELEMENT, METHOD OF MANUFACTURE THEREOF, AND MANUFACTURING SYSTEM OF SEMICONDUCTOR LIGHT EMITTING ELEMENT

(71) Applicant: Kaihara RYU, Osaka-shi (JP)

(72) Inventor: Kaihara RYU, Osaka-shi (JP)

(73) Assignee: Sharp Kabushiki Kaisha, Osaka-shi (JP)

(21) Appl. No.: 13/618,058

(22) Filed: Sep. 14, 2012

(30) Foreign Application Priority Data
Nov. 30, 2011 (JP) 2011-262698

(51) Int. Cl. H01L 33/04

(52) U.S. Cl. 257/13; 438/17; 118/712; 257/E33.008

(57) ABSTRACT

Manufacturing variation (production fluctuation) of designed doping concentration and the concentration distribution in the direction of depth can be inhibited and light emitting output can be improved and stabilized. A capacitance measuring step, wherein, after the formation of a p-type electrode 11 and an n-type electrode 12, the capacitance measuring section measures the capacitance between the p-type electrode 11 and the n-type electrode 12; an impurity concentration distribution computing step (not shown), wherein an impurity concentration distribution computing section computes the impurity concentration distribution from the measured capacitance; and a first impurity concentration distribution controlling step (not shown), wherein a first impurity concentration distribution controlling section controls by controlling the MOCVD section so that maximum light emitting output can be obtained at the time of the light emitting layer formation in the next lot or substrate, with the lowest value of the computed impurity concentration distribution as a characterizing amount.

This nonprovisional application claims priority under 35 U.S.C. §119(a) to Patent Application No. 2011-262698 filed in Japan on Nov. 30, 2011, the entire contents of which are hereby incorporated by reference.

### TECHNICAL FIELD

The present invention relates to a semiconductor light emitting element such as a nitride compound semiconductor light emitting element of a green, blue, or ultraviolet region and a method of manufacture thereof, and a manufacture system of a semiconductor light emitting element used in the method of manufacture of this semiconductor light emitting element.

### BACKGROUND ART

Conventionally, in this type of a conventional nitride semiconductor light emitting element, a nitride compound semiconductor light emitting element is widely used as a semiconductor light emitting element of a green, blue, or ultraviolet region. However, there is room for further improvement in the various characteristics of a nitride compound semiconductor light emitting element other than light emitting strength. Specifically, in regard to the electrostatic discharge withstand voltage, in comparison to a gallium or arsenic-based semiconductor light emitting element, or a indium or phosphorous-based semiconductor light emitting element, it is markedly cheaper and a substantial improvement in electrostatic discharge withstand voltage is expected.

Here, in order to improve the light emitting output of a conventional nitride semiconductor light emitting element, proposals for various structures in regard to the doping of an active layer (light emitting layer) are described in the following Cited References 1 and 2.

Patent Literature 1 describes that an active layer is formed by sequentially laminating a non-doped InGaN quantum well layer and a GaN barrier layer doped with an n-type impurity. Further, it is described that this GaN barrier layer doped with an n-type impurity is provided with a diffusion prevention film on the surface contacting the above-described InGaN quantum well layer. It is described that this diffusion prevention film comprises a lower concentration of n-type impurity than the GaN barrier layer.

FIG. 5 is a sectional side view illustrating a conventional semiconductor light emitting diode disclosed in Patent Literature 1.

As illustrated in FIG. 5, a conventional GaN semiconductor light emitting diode 100 is provided with a first nitride semiconductor layer 102 constituted of n-type GaN, an active layer 103 with a multi-quantum well structure, and a second nitride semiconductor layer 104 constituted of p-type AlGaN or p-type GaN on a sapphire substrate 101. On a top surface of the first nitride semiconductor layer 102 that is mesa-etched, an n-type electrode 106a is formed, on a top surface of the second nitride semiconductor layer 104, a transparent electrode layer 105 is formed, and a p-type electrode 106b is formed thereon.

The active layer 103 with a multi-quantum well structure is illustrated with four undoped GaN quantum barrier layers 103a and five InGaN quantum well layers 103b doped with an n-type impurity alternately laminated. However, there is no limit to the material or the number of the quantum barrier layers 103a and the quantum well layers 103b. For example, in a nitride semiconductor element, the quantum barrier layer 103a can be appropriately selected for use from Alₓ₁In_{y1}Ga_{1-x1-y1}N (x₁+y₁=1, 0≦x₁≦1, 0≦y₁1), and the quantum well layer 103b can be appropriately selected for use from Alₓ₂In_{y2}Ga_{1-x2-y2}N (x₂+y₂=1, 0≦x₂≦1, 0≦y₂≦1) as a material having a smaller energy band gap than the quantum barrier layer 103a.

On the other hand, Patent Literature 2 describes that an active layer comprises an n-type impurity, and the concentration of an n-type impurity in an active layer is higher in the n-layer side than the p-layer side.

FIG. 6 is a sectional side view illustrating a conventional nitride semiconductor light emitting element disclosed in Patent Literature 2.

In FIG. 6, a conventional nitride semiconductor light emitting element 200 comprises a substrate 201 laminated with a buffer layer 202, an undoped GaN layer 203, an n-type contact layer 204 constituted of GaN doped with Si, an n-type first multi-layer film layer 205, an n-type second multi-layer film layer 206, an active layer 207 with a multi-quantum well structure constituted of InGaN/GaN, a p-type multi-layer film layer 208, and a p-type contact layer 209 constituted of GaN doped with Mg. The composition and/or the number of layers of nitride semiconductor constituting the n-type multilayer film layer 206 and the p-type multi-layer film layer 208 are different for each of n-type and p-type.

The active layer 207 with a multi-quantum well structure has a multi-quantum well structure with a multi-layer film structure in which a well layer and a barrier are alternately laminated sequentially. For the smallest laminated structure of a multi-quantum well structure, a three layer structure constituted of one barrier layer and two well layers provided on both sides of the barrier layer, or a three layer structure constituted of one well layer and two barrier layers provided on both sides thereof is considered. In a multi-quantum well structure, the two outermost layers on both sides are constituted with well layers or barrier layers. Further, it may be configured such that one of the outermost layers is a well layer and the other outermost layer is a barrier layer. Further, in a multi-quantum well structure, the p-layer side may end with a barrier layer or a well layer.

### CITATION LIST

### Patent Literature

Patent Literature 1: Japanese Laid-Open Publication No. 2005-109425
Patent Literature 2: Japanese Laid-Open Publication No. 2005-057308

### SUMMARY OF THE INVENTION

### Technical Problem

In either of the above-described conventional configurations, improvement in the light emitting output of a semiconductor light emitting element is possible. However, drive voltage related to the n-type doping concentration and electrostatic discharge withstand voltage are generally in a trade-off relationship, and it is difficult to determine an optimal doping concentration and an optimal solution of a distribution of the concentration in the direction of depth. Moreover, in a production factory, during continuous manufacturing of semiconductor light emitting elements, growth temperature, gas composition, or the like of an active layer continuously drifts and the quality of a crystal that grows changes. Thus, it cannot be judged whether the designed doping concentration and a distribution of the concentration in the direction of depth are constantly optimal. Specifically, the designed doping concentration and the distribution of the concentration in the direction of depth greatly vary due to change in growth temperature and in the gas composition of the active layer.

For this reason, in a manufacturing factory, light emitting output of a manufactured semiconductor light emitting element frequently fluctuates depending on the manufacturing date and time of a product, and it is especially prominent in an LED using a nitride semiconductor.

The present invention is intended to solve the conventional problems described above. It is an objective of the present invention to provide a method of manufacture of a semiconductor light emitting element that is capable of inhibiting manufacturing variation (production fluctuation) in designed doping concentration and the distribution of the concentration in the direction of depth, and improve and stabilize light emitting output, a semiconductor light emitting element manufactured thereby, and a manufacturing system of a semiconductor light emitting element using the method of manufacture of this semiconductor light emitting element.

### Solution to Problem

A method of manufacture of a semiconductor light emitting element according to the present invention for forming a light emitting layer with a multi-quantum well structure on a monocrystalline substrate by an MOCVD section and for forming a p-type electrode and an n-type electrode to supply a current to the light emitting layer is provided, comprising: a capacitance measuring step, where, after the formation of the p-type electrode and the n-type electrode, a capacitance measuring section measures the capacitance between the p-type electrode and the n-type electrode; an impurity concentration distribution computing step, where an impurity concentration distribution computing section computes an impurity concentration distribution of the light emitting layer from measured capacitance; and a first impurity concentration distribution controlling step, where a first impurity concentration distribution controlling section controls impurity concentration so that maximum light emitting output can be obtained at a time of formation of the next light emitting layer, with a lowest value of impurity concentration of a computed impurity concentration distribution as a characterizing amount, thereby achieving an objective described above.

Preferably, in a method of manufacture of a semiconductor light emitting element according to according to the present invention, the first impurity concentration distribution controlling step controls an impurity concentration distribution in at least a barrier layer of a well layer and the barrier layer of the light emitting layer.

Still preferably, in a method of manufacture of a semiconductor light emitting element according to the present invention, the first impurity concentration distribution controlling step controls so that a single conductive type impurity concentration distribution is in a range of 5×10¹⁶ cm⁻³ to 9×10¹⁶ cm⁻³, with a lowest value thereof as a characterizing amount.

Still preferably, in a method of manufacture of a semiconductor light emitting element according to the present invention, the first impurity concentration distribution controlling step controls so that a single conductive type impurity concentration distribution is at 7×10¹⁶ cm⁻³, with a lowest value thereof as a characterizing amount.

Still preferably, in a method of manufacture of a semiconductor light emitting element according to the present invention, the first impurity concentration distribution controlling step controls a minimum value of the impurity concentration distribution by controlling a flow amount of SiH₄ gas and/or SiH(CH₃)₃ gas at a time of growth of at least a barrier layer of a well layer and the barrier layer of the light emitting layer.

Still preferably, in a method of manufacture of a semiconductor light emitting element according to the present invention, the first impurity concentration distribution controlling step controls a minimum value of the impurity concentration distribution by controlling an introduction time of SiH₄ gas and/or SiH(CH₃)₃ gas at a time of growth of at least a barrier layer of a well layer and the barrier layer of the light emitting layer.

Still preferably, in a method of manufacture of a semiconductor light emitting element according to the present invention, the capacitance measured in the capacitance measuring step is a value that is measured by superimposing and applying at least one type of direct voltage and alternating voltage between the p-type electrode and the n-type electrode.

Still preferably, in a method of manufacture of a semiconductor light emitting element according to the present invention, the capacitance measured in the capacitance measuring step is a value that is measured by superimposing and applying at least one type of pulse voltage and alternating voltage between the p-type electrode and the n-type electrode.

Still preferably, in a method of manufacture of a semiconductor light emitting element according to the present invention, a frequency of the alternating voltage is 100 kHz to 10 MHz.

Still preferably, in a method of manufacture of a semiconductor light emitting element according to the present invention, an amplitude of the alternating voltage is 5 mV to 30 mV.

Still preferably, in a method of manufacture of a semiconductor light emitting element according to the present invention, the direct voltage is in a range of 0.8V to 2.8V, with the p-electrode as positive.

Still preferably, in a method of manufacture of a semiconductor light emitting element according to the present invention, the impurity concentration distribution is an n-type impurity concentration distribution, and the impurity is Si.

Still preferably, in a method of manufacture of a semiconductor light emitting element according to the present invention, a multilayer alternately laminated with a first layer constituted of InₓGa₁₋ₓN (0<x<0.3) and a second layer constituted of GaN is formed on the n-electrode side of the light emitting layer with the multi-quantum well structure on the monocrystalline substrate by the MOCVD method, and as the light emitting layer, a well layer constituted of In_{y}Ga_{1-y}N (0<y<0.3) comprising at least In and a barrier layer constituted of In_{y}Al_{z}Ga_{1-y-z}N (0≦y<0.1, 0≦z<0.2) are formed.

Still preferably, in a method of manufacture of a semiconductor light emitting element according to the present invention, impurity is added at a single conductive type impurity concentration in a range of 5×10¹⁶ cm⁻³ to 5×10¹⁸ cm⁻³, to at least a barrier layer of the light emitting layer.

Still preferably, a method of manufacture of a semiconductor light emitting element according to the present invention is provided, further comprising: a light emitting output and drive voltage inspecting step, wherein a light emitting output and drive voltage inspecting section measures light emitting output and drive voltage for inspection; and a second impurity concentration distribution controlling step, where a second impurity concentration distribution controlling section controls the impurity concentration distribution of the light emitting layer by controlling the MOCVD section so as to minimize an increase of the drive voltage while obtaining maximum light emitting output in accordance with the measured light emitting output and drive voltage at a time of formation of a next light emitting layer, when at least one of the measured light emitting layer and the drive voltage exceeds a predetermined range.

A semiconductor light emitting element manufactured by the method of manufacture of a semiconductor light emitting element according to the present invention is provided, where a lowest value of a single conductive type impurity concentration distribution in at least a barrier layer of a well layer and the barrier layer of the light emitting layer is in a range of 5×10¹⁶ cm⁻³ to 9×10¹⁶ cm⁻³, thereby achieving an objective described above.

Preferably, in a semiconductor light emitting element according to the present invention, the lowest value of the single conductive type impurity concentration distribution is at a tolerance of 7×10¹⁶ cm⁻³.

A manufacturing system of a semiconductor light emitting element for forming a light emitting layer with a multi-quantum well structure on a monocrystalline substrate by an MOCVD section and for forming a p-type electrode and an n-type electrode to supply a current to the light emitting layer is provided, comprising a capacitance measuring section for measuring the capacitance between the p-type electrode and the n-type electrode after the formation of the p-type electrode and the n-type electrode; an impurity concentration distribution computing section for computing an impurity concentration distribution of the light emitting layer from measured capacitance; and a first impurity concentration distribution controlling section for controlling so that maximum light emitting output can be obtained at a time of formation of the next light emitting layer, with a lowest value of impurity concentration of a computed impurity concentration distribution as a characterizing amount, thereby achieving an objective described above.

Preferably, in a manufacturing system of a semiconductor light emitting element according to the present invention, the first impurity concentration distribution controlling section controls an impurity concentration distribution in at least a barrier layer of a well layer and the barrier layer of the light emitting layer.

Still preferably, in a manufacturing system of a semiconductor light emitting element according to the present invention, the first impurity concentration distribution controlling step controls so that a single conductive type impurity concentration distribution is in a range of 5×10¹⁶ cm⁻³ to 9×10¹⁶ cm⁻³, with a lowest value thereof as a characterizing amount.

Still preferably, in a manufacturing system of a semiconductor light emitting element according to the present invention, the first impurity concentration distribution controlling step controls so that a single conductive type impurity concentration distribution is at 7×10¹⁶ cm⁻³, with a lowest value thereof as a characterizing amount.

Still preferably, in a manufacturing system of a semiconductor light emitting element according to the present invention, the first impurity concentration distribution controlling step controls a minimum value of the impurity concentration distribution by controlling a flow amount of SiH₄ gas and/or SiH(CH₃)₃ gas at a time of growth of at least a barrier layer of a well layer and the barrier layer of the light emitting layer.

Still preferably, in a manufacturing system of a semiconductor light emitting element according to the present invention, the first impurity concentration distribution controlling step controls a minimum value of the impurity concentration distribution by controlling an introduction time of SiH₄ gas and/or SiH(CH₃)₃ gas at a time of growth of at least a barrier layer of a well layer and the barrier layer of the light emitting layer.

Still preferably, a manufacturing system of a semiconductor light emitting element according to the present invention is provided, further comprising a light emitting output and drive voltage inspecting section for measuring the light emitting output and drive voltage for inspection; and a second impurity concentration distribution controlling section for controlling the impurity concentration distribution of the light emitting layer by controlling the MOCVD section so as to minimize an increase of the drive voltage while obtaining maximum light emitting output in accordance with the measured light emitting output and drive voltage at a time of formation of a next light emitting layer, when at least one of the measured light emitting layer and the drive voltage exceeds a predetermined range.

The functions of the present invention having the structures described above will be described hereinafter.

How a production fluctuation of designed doping concentration and distribution of the concentration in the direction of depth are detected and how they are inhibited will be explained.

In the present invention, a method of manufacture of a semiconductor light emitting element for forming a light emitting layer of a multi-quantum well structure on a monocrystalline substrate by an MOCVD section and forming a p-type electrode and an n-type electrode for supplying a current to the light emitting layer comprises: a capacitance measuring step wherein a capacitance measuring section measures the capacitance between the p-type electrode and the n-type electrode after the formation of the p-type electrode and the n-type electrode; an impurity concentration distribution computing step wherein an impurity concentration distribution computing section computes an impurity concentration distribution from the measured capacitance; and a first impurity concentration distribution controlling step wherein a first impurity concentration distribution controlling section controls the MOCVD section so that maximum light emitting output can be obtained at the formation of the next light emitting layer, with impurity concentration of the computed impurity concentration distribution using the lowest value as the characterizing amount.

In this manner, since controlling impurity concentration enables maximum light emitting output to be obtained with impurity concentration of the impurity concentration distribution computed from the measured capacitance using the lowest value as a characterizing amount, it becomes possible to inhibit manufacturing variation (production fluctuation) in the designed doping concentration and distribution in the direction of depth to improve and stabilize light emitting output.

### Advantageous Effects of Invention

According to the present invention described above, since controlling the impurity concentration enables the maximum light emitting output to be obtained with an impurity concentration of the impurity concentration distribution computed from the measured capacitance using the lowest value as a characterizing amount, it becomes possible to inhibit manufacturing variation (production fluctuation) in the designed doping concentration and distribution in the direction of depth to improve and stabilize light emitting output.

### BRIEF DESCRIPTION OF THE DRAWINGS

FIG. 1 is a cross-sectional view illustrating an example of a configuration of an essential part of a nitride semiconductor light emitting element according to Embodiment 1 of the present invention.

FIG. 2 is a representative diagram illustrating capacitance measurement results by the C-V method of FIG. 1 as characteristic curves of depletion layer width x (μm) and carrier density (cm⁻³).

FIG. 3 is a diagram illustrating the relationship between the minimum carrier concentration N of the measured results A-D of FIG. 2, and the light emitting output of the nitride semiconductor light emitting element 1 and drive voltage at this time.

FIG. 4 is a flow chart illustrating each manufacturing step in the method of manufacture of the nitride semiconductor light emitting element 1 of FIG. 1.

FIG. 5 is a sectional side view illustrating a conventional semiconductor light emitting diode disclosed in Patent Literature 1.

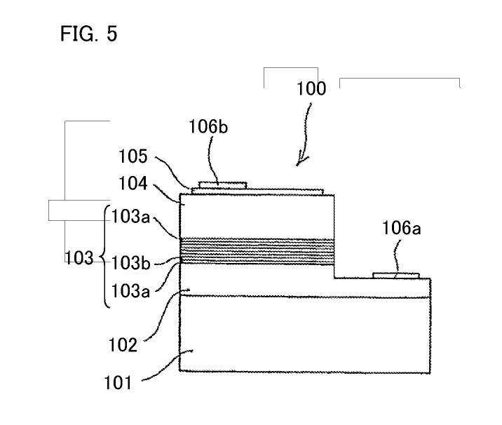

FIG. 6 is a sectional side view illustrating a conventional nitride semiconductor light emitting element disclosed in Patent Literature 2.

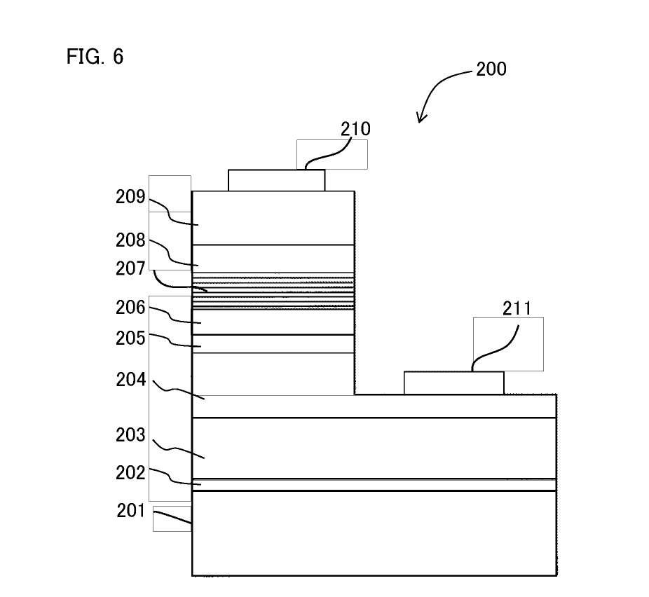

### REFERENCE SIGNS LIST

1 nitride semiconductor light emitting element
2 sapphire substrate
3 buffer layer
4 undoped GaN layer
5 n-type contact layer
6 multilayer
7 light emitting layer with a multi-quantum well structure
8 electric block layer
9 p-type contact layer
10 translucent thin film electrode
12 n-electrode
11 p-electrode
13 protective layer

### DESCRIPTION OF THE PREFERRED EMBODIMENTS

Hereinafter, a case where a semiconductor light emitting element, a method of manufacture thereof, and a manufacturing system of a semiconductor light emitting element of the present invention are applied to Embodiment 1 of a nitride semiconductor light emitting element, a method of manufacture thereof, and a manufacturing system of a nitride semiconductor light emitting element will be described in detail with reference to the accompanying figures.

### Embodiment 1

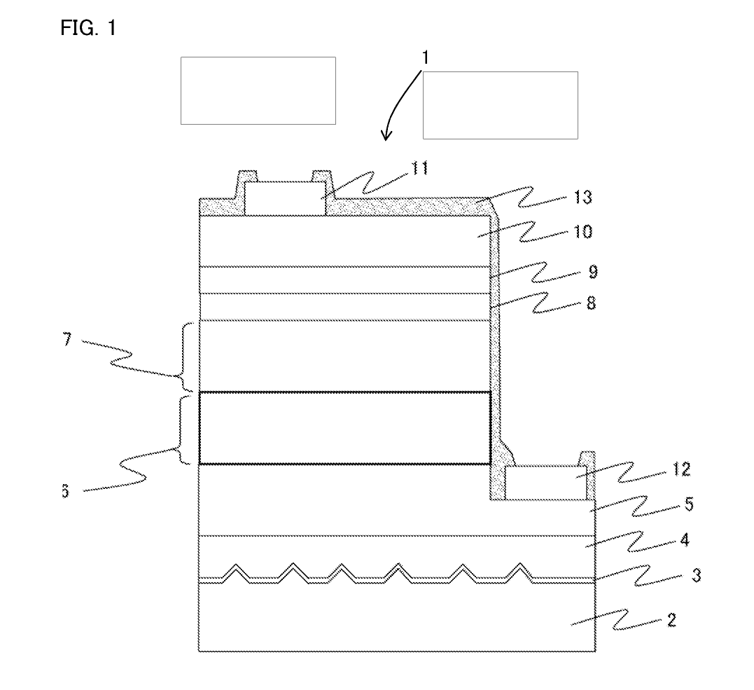

FIG. 1 is a cross-sectional view illustrating an example of a configuration of an essential part of a nitride semiconductor light emitting element according to Embodiment 1 of the present invention.

In FIG. 1, in a nitride semiconductor light emitting element 1 according to Embodiment 1, for example, on a sapphire substrate 2 as a substrate with a thickness of about 300 μm where unevenness with triangular cross-section is formed on a surface, a buffer layer 3 with a film thickness of about 15 nm constituted of aluminum nitride (AlN) is deposited, and an undoped GaN layer 4 with a film thickness of about 500 nm constituted of undoped GaN is deposited thereon. The sapphire substrate 2, buffer layer 3, and undoped GaN layer 4 constitute a monocrystalline substrate.

Further, in the nitride semiconductor light emitting element 1 according to Embodiment 1, an n-type contact layer 5 (high carrier concentration n⁺ layer) with a film thickness of about 5 μm constituted of GaN doped with 1×10¹⁸/cm³ of silicon (Si) is formed on this monocrystalline substrate. A multilayer 6 is formed on this n-type contact layer 5, and a light emitting layer 7 with a multi-quantum well structure is formed on this multilayer 6.

This multilayer 6 is laminated with a plurality of first layers constituted of InₓGa₁₋ₓN (0<x<0.3) and second layers constituted of GaN alternately. Here, for example, this multilayer 6 is laminated with five pairs of first layers constituted of In_{0.02}Ga_{0.98}N with a film thickness of 2.5 nm and second layers constituted of GaN with a film thickness of 3 nm. Si is added as a single conductive type impurity to the first layers of this multilayer 6, with concentration of the impurity in the range of 1×10¹⁶ cm⁻³ to 5×10¹⁸ cm⁻³ (still preferably, 5×10¹⁶ cm⁻³ to 5×10¹⁷ cm⁻³).

A well layer of the light emitting layer 7 with a multi-quantum well structure is constituted of In_{y}Ga_{1-y}N (0≦y<0.3) comprising at least In. In this manner, here, for example, the light emitting layer 7 with a multi-quantum well structure is laminated with six pairs of well layers constituted of In_{0.2}Ga_{0.8}N with a film thickness of 3 nm and barrier layers constituted of GaN with a film thickness of 5 nm.

Further, in the nitride semiconductor light emitting element 1 according to Embodiment 1, on this light emitting layer 7, an electric block layer 8 is formed, which is a p-type layer constituted of p-type Al_{0.15} Ga_{0.85}N doped with 2×10¹⁹ (cm⁻³) of Mg and having a film thickness of 25 nm, and on this electric block layer 8, a p-type contact layer 9 constituted of p-type GaN doped with 8×10¹⁹ (cm⁻³) of Mg, with a film thickness of 100 nm is formed. On this p-type contact layer 9, a translucent thin film electrode 10 (ITO) is formed by metal deposition. On a part of the translucent thin film electrode 10, a p-electrode 11 is formed, and on the other hand, an n-electrode 12 is formed on an edge section of the n-type contact layer 5. On the topmost section, a protective film 13 constituted of SiO₂ is formed. The translucent thin film electrode 10 is constituted of a first layer with a film thickness of about 1.5 nm, which is constituted of nickel (Ni) and directly bonds to the p-type contact layer 9, and a second layer with a film thickness of about 6 nm, which is constituted of gold (Au) and directly bonds to this nickel film.

Specifically, in the nitride semiconductor light emitting element 1 according to Embodiment 1: a buffer layer 3 and an undoped GaN layer 4 are formed in this order on a sapphire substrate 2 to constitute a monocrystalline substrate; two repeated layers of multilayers 6, two repeated layers of light emitting layers 7 with a multi-quantum well structure, and an electric block layer 8 are formed in this order between an n-type contact layer 5 and a p-type contact layer 9 on this monocrystalline substrate; a p-electrode 11 is formed on the p-type contact layer 9, with a translucent thin film electrode 10 that is an ohmic contact interposed therebetween; an n-electrode 12 is formed on a part of the n-type contact 5; and on the topmost part, a protective film 13 for moisture-proofing is formed.

The multi-quantum well structure constituting the light emitting layer 7 comprises a well layer constituted of group III nitride compound semiconductor InₓGa₁₋ₓN (0<x<0.3) comprising at least indium (In). The configuration of the light emitting layer 7 has, for example, a well layer constituted of doped or undoped In_{y}Ga_{1-y}N (0<y<0.3), and a barrier layer constituted of a group III nitride compound semiconductor GaN, In_{y}Ga_{1-y}N (0<y<0.1) of any composition with a greater band gap than this well layer or of In_{y}Al_{z}Ga_{1-y-z}N (0<y<0.1, 0<z<0.2). As a preferable example, there is a barrier wall constituted of undoped In_{y}Ga_{1-y}N (0<y<0.1).

The multilayer 6 provided on the n-electrode 12 side of the light emitting layer 7 is formed with a layer constituted of In_{w}Ga_{1-w}N (0<w<0.3) having a composition w of indium (In) that is smaller than the composition x of indium (In) of a well layer constituted of group III nitride compound semiconductor InₓGa₁₋ₓN (0<x<0.3) comprising at least indium (In), which forms the light emitting layer 7. At this time, it is preferable that the composition w of indium (In) of the layer constituted of In_{w}Ga_{1-w}N (0<w<0.3) that forms the multilayer 6 is greater than or equal to 0.02 and less than or equal to 0.07, or still preferably, greater than or equal to 0.03 and less than or equal to 0.05.

It is preferable that the film thickness of the layer constituted of (0<w<0.3) of the multilayer 6 provided on the n-electrode 12 side of the light emitting layer 7 is greater than or equal to 0.5 nm and less than or equal to 6 nm, and still preferably, greater than or equal to 0.5 nm and less than or equal to 4 nm. Although the light emitting characteristics will be shown below, it is known that drive voltage Vf markedly increases if the film thickness of a layer constituted of In_{w}Ga_{1-w}N (0<w<1) exceeds 6 nm. Film thickness of less than 0.5 nm should be avoided, as adjustment thereof becomes difficult. On the other hand, it is known that for the layer constituted of GaN of the multilayer 6, a large change in element characteristic does not occur at least in the range of 10-40 nm. It is desirable that the ratio of the thickness of the layer constituted of In_{w}Ga_{1-w}N (0<w<0.3) of the multilayer 6 to the thickness of the well layer of the light emitting layer is greater than or equal to 0.1 and less than or equal to 2. It is still desirable that the thickness of the layer constituted of In_{w}Ga_{1-w}N (0<w<0.3) of the multilayer 6 is adjusted to the thickness of the well layer of the light emitting layer 7 or less. On the other hand, it is desirable that the ratio of the thickness of the layer constituted of GaN of the multilayer 6 to the thickness of the barrier layer of the light emitting layer 7 is greater than or equal to 0.5 and less than or equal to 4. It is still desirable that the thickness of the layer constituted of GaN of the multilayer 6 is adjusted to the thickness of the barrier layer of the light emitting layer 7 or greater.

It is desirable that the number of layers constituting In_{w}Ga_{1-w}N (0<w<0.3) of the multilayer 6 provided on the n-type electrode 12 side of the light emitting layer 7 is greater than or equal to one and less than or equal to thirty, and still preferably greater than or equal to three and less than or equal to twenty.

The nitride semiconductor light emitting element 1 such as group III nitride compound semiconductor light emitting element can take on any configuration, other than the above-described limitation related to the primary configuration of the invention. Further, the nitride semiconductor light emitting element 1 can be a light emitting diode (LED), laser diode (LD), photocoupler, or any other light emitting element. Specifically, any method of manufacture can be used as the method of manufacture of nitride semiconductor light emitting element 1 such as group III nitride compound semiconductor light emitting element defined by the present invention.

In more detail, as a substrate for growing a crystal, sapphire, spinel, Si, SiC, ZnO, MgO, group III nitride compound monocrystal, or the like can be used. As a method for growing a crystal on a group III nitride compound semiconductor layer, molecular beam epitaxy (MBE), metal organic chemical vapor deposition (MOCVD), halide vapor phase epitaxy (HDVPE), liquid phase epitaxy, or the like is effective.

Group III nitride semiconductor layer such as an electrode forming layer can be formed at least with group III nitride compound semiconductor constituted of binary, ternary, or quaternary semiconductor represented by AlₓGayIn_{1-x-y}N (0≦x≦0.3, 0.7≦y≦1, 0≦x+y≦1).

Here, as a featured configuration of the nitride semiconductor light emitting element 1 according to Embodiment 1, in the light emitting layer 7, a first layer constituted of InₓGa₁₋ₓN (0<x<0.3) and a second layer constituted of GaN are alternately laminated, and in at least the barrier layer of this light emitting layer 7, Si is added as a single conductive type impurity, with the concentration in the range of 5×10¹⁶ cm⁻³ to 5×10¹⁸ cm⁻³ (still preferably, 5×10¹⁶ cm⁻³ to 5×10¹⁷ cm⁻³).

This featured configuration of nitride semiconductor light emitting element 1 according to Embodiment 1 will be described in more detail hereinafter.

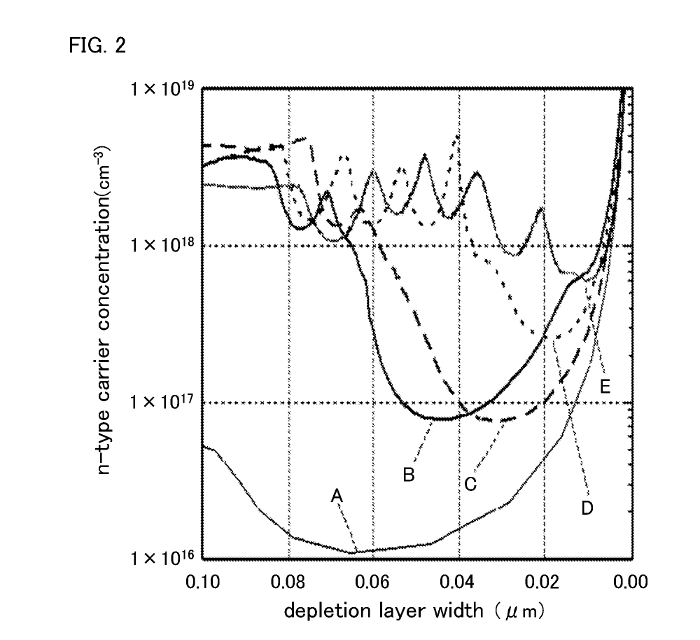

FIG. 2 is a representative diagram illustrating capacitance measurement results by the C-V method of FIG. 1 as characteristic curves of depletion layer width x (μm) and carrier density (cm⁻³).

As illustrated in FIG. 2, for example, waveforms A-D are characteristic curves of depletion layer width x (μm) to carrier density (cm⁻³), which are results of capacitance measurements per lot. The method of measurement of n-type impurity concentration is performed by measuring capacitance. Specifically, direct voltage Vdc and alternating voltage Vac are superimposed and the superimposed direct voltage Vdc and alternating voltage are applied between the p-type electrode 11 and the n-type electrode 12 of the nitride semiconductor light emitting element 1 to measure capacitance amount from the measurement result of the complex impedance. Commonly, it is called a C-V (Capacitance-Voltage) method. The method for calculating concentration at any depth of a light emitting layer by the C-V method is as follows. Direct voltage Vdc in the C-V method is applied by changing the intervals in four groups, the range of direct voltage of 3 to 2 V in 0.02V intervals, the range of direct voltage of 2 to 0V in 0.1V intervals, the range of direct voltage of 0 to −10V in 0.2V intervals, and the range of direct voltage of −10 to −20V in 1V intervals. Amplitudes of alternating voltage V_{dc} with a 1 MHz frequency that is simultaneously superimposed therewith are 0.01V, 0.05V, 0.1V, and 0.5V in the above-described divided direct voltage ranges, respectively. In Embodiment 1, the range of direct voltage is divided into four ranges. It is not an issue if the range is not divided, or divided into other numbers of ranges. However, it is preferable that the range is divided into 2 to 4 ranges in a light emitting element using nitride semiconductor. Further, it is preferable that the amplitude of alternating voltage Vac is half of the width of direct voltage intervals in each of the ranges of direct voltage. This is because n-type impurity concentration of all regions of the nitride semiconductor light emitting element 1 can be measured by setting instant voltage at the time of measuring capacitance by the C-V method so that there is no break in all the ranges of voltage. Thereafter, set direct voltage V_{dc} and measured capacitance C are converted to depletion layer x and carrier density N.

When alternating voltage Vac and direct voltage Vdc are superimposed and applied between the n-side electrode 12 and the p-side electrode 11 of the nitride semiconductor light emitting element 1 to measure depletion layer capacity C, or specifically, when C-V characteristic of the nitride semiconductor light emitting element 1 is examined, thickness x of a depletion layer is calculated from formula 1 described below.

Here, the thickness x of a depletion layer is primarily a depletion layer formed in an n-type semiconductor layer, with the electric block layer 8 (p-type semiconductor) and the light emitting layer 7 with a multi-quantum well structure (approximately n-type semiconductor) of the nitride semiconductor light emitting element 1 as the boundary. A depletion layer width x is synonymous with the depth of the light emitting layer 7 with a multi-quantum well structure, viewed from the electric block layer 8.

x=∈₀∈ᵣ/C formula 1.

In formula 1, x is the thickness of a depletion layer (cm), and ∈₀ is a dielectric constant in a vacuum (8.9×10⁻¹⁴(F/cm)). ∈ᵣ is a relative dielectric constant of a nitride semiconductor light emitting material (unit is dimensionless), and can be approximated with the relative dielectric constant of GaN in Embodiment 1. C is a measured depletion layer capacity (F/cm²).

Further, when the size of the voltage applied to the nitride semiconductor light emitting element 1 changes, the thickness of a depletion layer (thickness of depletion layer x) changes, and the depletion layer capacity changes. Here, carrier concentration N in the bottom surface of a depletion layer (surface of a depletion layer positioned on the substrate 3 side) is represented by formula 2 described below. For this reason, when the size of the voltage V applied to the nitride semiconductor light emitting element 1 is changed and the depletion layer capacity C is measured, the carrier concentration N in the bottom surface of a depletion layer is calculated from the formula 2 described below.

N=C³/{q∈₀∈ᵣ(ΔC/ΔV_{dc})} formula 2.

In formula 2, N is the carrier concentration (1/cm³) in the bottom surface of a depletion layer; q is the point charge amount (C); ΔC is the change in depletion layer capacity when the size of voltage V applied to the nitride semiconductor light emitting element 1 changes; and ΔVdc is the change in direct voltage Vdc applied to the nitride semiconductor light emitting element 1. Each of C, ∈₀, and ∈ᵣ in formula 2 is the same as in formula 1. From the above, if the size of voltage V applied to the nitride semiconductor light emitting element 1 is changed and the depletion layer capacity C is measured, the relationship between thickness x of a depletion layer and the carrier concentration N in the bottom surface of the depletion layer can be found. Specifically, the carrier concentration of the light emitting layer 7≈n-type impurity concentration=distribution of depth of Si doping concentration can be measured by changing the applied direct voltage V_{dc} in any way.

As illustrated in FIG. 2, the n-type carrier concentration (silicon concentration) is at its lowest in the vicinity of depth 0.06 μm from the surface of the light emitting layer 7 in measurement result A. Further, in measurement result E, the n-type carrier concentration is at its lowest in the vicinity of depth 0.01 μm from the surface of the light emitting layer 7. In this manner, the doping concentration corresponding to a desired depth from the surface of the light emitting layer 7 (impurity concentration distribution in the direction of depth, or carrier concentration) can be detected. Even if active layers are grown under the same conditions, manufacturing variance (production fluctuation) occurs as in measurement results A-E due to a change in the film growth temperature, change in gas composition, or the like.

Si is doped to grow a film in MOCVD, but the growth temperature and gas composition of an active layer also changes. Thus, measurement result A occurs when the amount of supplied silane gas for supplying Si in MOCVD is low. Further, even if the supply of silane gas supplying Si in MOCVD is constant at a predetermined value, measurement result A occurs when a film growth temperature is high so that film growth is fast and Si concentration is low. In contrast, measurement result E occurs when supply of silane gas supplying Si in MOCVD is high. Further, even if the supply of silane gas supplying Si in MOCVD is constant at a predetermined value, measurement result E occurs when a film growth temperature is low so that the film growth is slow and the Si concentration is high. In this manner, the production finish of the light emitting layer 7 is readily detected by detecting doping concentration (distribution in the direction of depth) corresponding to a desired depth from the surface of the light emitting layer 7 by the C-V method.

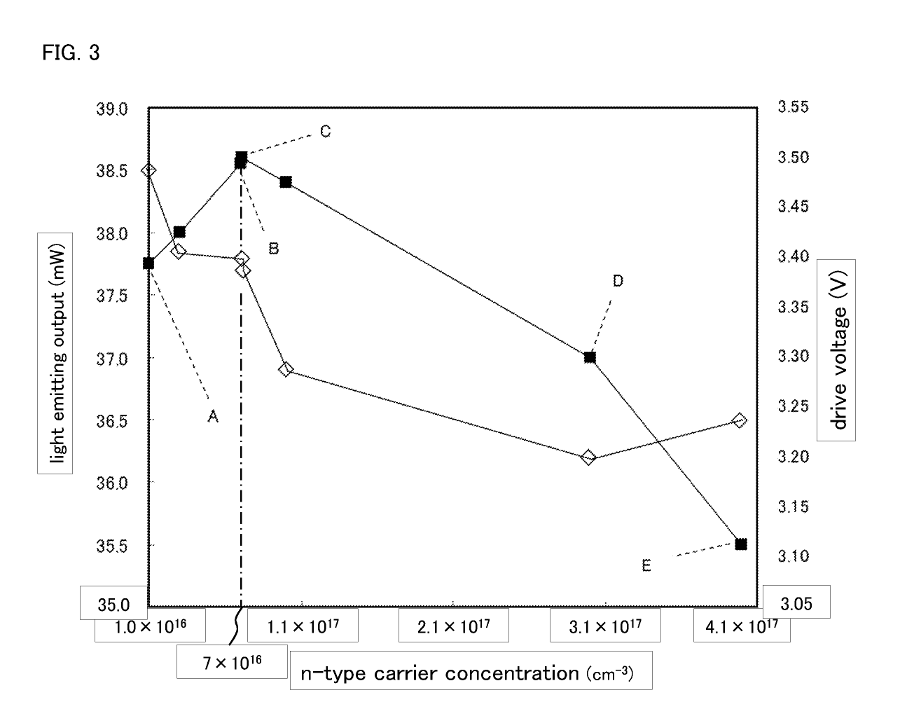

FIG. 3 is a diagram illustrating the relationship between the minimum carrier concentration N of the measured results A-D of FIG. 2, and the light emitting output of the nitride semiconductor light emitting element 1 and drive voltage at this time. Black squares illustrate the relationship between the minimum carrier concentration N to the light emitting output, and white squares illustrate the relationship between the minimum carrier concentration N to drive voltage.

As illustrated in FIG. 3, the light emitting output was measured with a photodiode. In the measurement result of Embodiment 1, the light emitting output is at its maximum when the carrier concentration is 5×10¹⁶ to 9×10¹⁶ (cm⁻³), and when the carrier concentration is lower or higher than this value, light emitting output decreases. On the other hand, there was a tendency of the drive voltage being lower when the carrier concentration is low, and being higher when the carrier concentration is high. Specifically, if Si is doped to be in the vicinity of 7×10¹⁶ (cm⁻³), an increase of drive voltage is minimized while the maximum light emitting output is obtained.

In FIG. 3, the light emitting output is at its maximum when N-type carrier concentration is at 7×10¹⁶ (cm⁻³), as in measurement results B and C, and the light emitting output decreases in the back and front thereof. On the other hand, as illustrated by the white squares, the relationship between the minimum carrier concentration N and drive voltage is a diagram of a characteristic curve that slopes down to the right. The lower the drive voltage measured by letting a constant related current flow between the p-electrode 11 and the n-electrode 12, the more energy efficient it is. Thus, when the growth temperature, gas composition, or the like of the active layer continuously drifts to be measurement results A, D, or E, the light emitting output decreases.

In light of this, by detecting the doping concentration (distribution in the direction of depth) corresponding to the desired depth from the surface of the light emitting layer 7 by the C-V method and continuously controlling the growth temperature, gas composition, or the like of the active layer to be measurement results B or C, a decrease in light emitting output as in measurements A, D, and E can be prevented.

The method of manufacture of the nitride semiconductor light emitting element 1 with the above-described configuration will be described below.

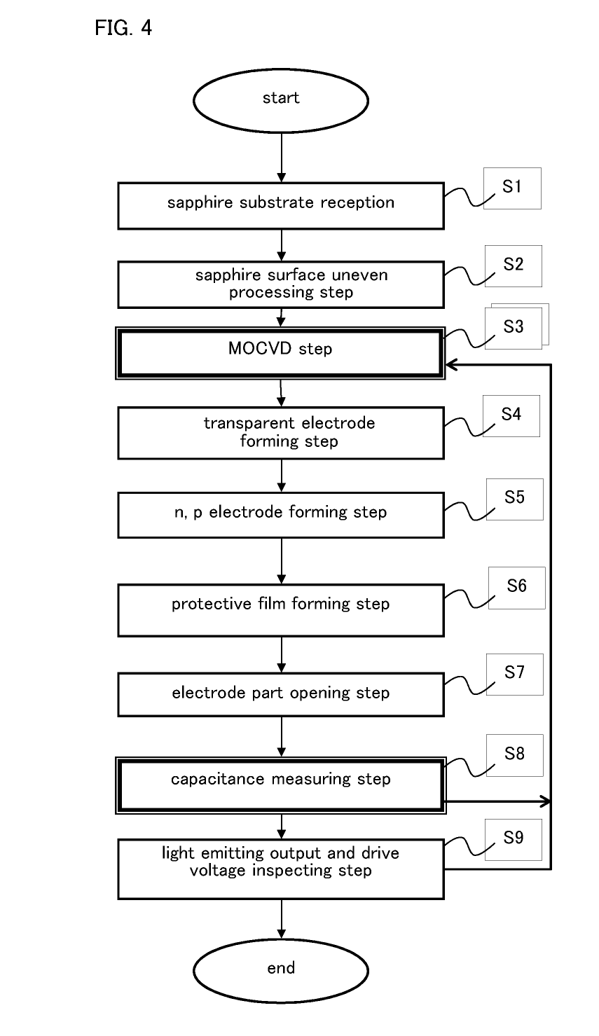

FIG. 4 is a flow chart illustrating each manufacturing step in the method of manufacture of the nitride semiconductor light emitting element 1 of FIG. 1.

As illustrated in FIG. 4, the method of manufacture of the nitride semiconductor light emitting element 1 of Embodiment 1 comprises: a substrate receiving step of sapphire substrate 2, wherein a substrate receiving section receives a sapphire substrate 2 at a predetermined position in step S1; a sapphire surface uneven processing step, wherein a sapphire surface uneven processing section forms triangular unevenness on a surface of the sapphire substrate 2 in step S2; an MOCVD step, wherein by an MOCVD method, an MOCVD section forms a buffer layer 3, undoped GaN layer 4, an n-type contact layer 5, a multilayer 6, a light emitting layer 7 with a multi-quantum well structure, an electric block layer 8, and a p-type contact layer sequentially in this order on a surface uneven processing surface of the sapphire substrate 2 in step S3; a transparent electrode forming step, wherein a transparent electrode forming section forms a translucent thin film electrode 10 on the p-type contact layer 9 in step S4; an n-electrode and p-electrode forming step, wherein an n-electrode and p-electrode forming section etches to remove an edge part of the substrate to apart of the n-type contact layer 5 to expose an edge part of the n-type contact layer 5 to form an n-electrode 12 on the edge part surface of the n-type contact layer 5, and to form a p-electrode 11 on a part of a surface of the translucent thin film electrode 10 in step S5; a protective layer forming step, wherein a protective layer forming section forms a protective layer 13 on exposed surfaces of the translucent thin film electrode 10, p-electrode 11, n-electrode 12, n-type contact layer 5, and further on a side surface etched for removal for moisture-proofing in step S6; an electrode opening section step, wherein an electrode opening section opens each of the protective layers 13 on the p-electrode 11 and the n-electrode 12 in step S7; a capacitance measuring step, wherein a capacitance measuring section measures the capacitance between the n-electrode 12 and the p-electrode 11 in step S8; an impurity concentration distribution computing step, wherein an impurity concentration distribution computing section computes the impurity concentration distribution from the measured capacitance in step S8; a first impurity concentration distribution controlling step, wherein a first impurity concentration distribution controlling section controls the minimum value of the impurity concentration distribution by controlling the MOCVD section so that maximum light emitting output can be obtained at the time of the next light emitting layer formation by comparing a standard value to the lowest value of the computed impurity concentration distribution as a characterizing amount when the minimum value of the computed impurity concentration distribution exceeds a predetermined range in step S8; a light emitting output and drive voltage inspecting step, wherein a light emitting output and drive voltage inspecting section inspects light emitting output and drive voltage in step S9; and a second impurity concentration distribution controlling step, wherein a second impurity concentration distribution controlling section controls the impurity concentration distribution by controlling the MOCVD method so as to minimize the increase of drive voltage while obtaining the maximum light emitting output in accordance with the measured light emitting output and drive voltage at the next light emitting layer formation when the measured light emitting output and drive voltage exceeds a predetermined range.

The manufacturing system of the nitride semiconductor light emitting element 1 of Embodiment 1 comprises: a substrate receiving section of a sapphire substrate 2 for receiving the sapphire substrate 2 at a predetermined position; a sapphire surface uneven processing section for forming triangular unevenness on the surface of the sapphire substrate 2; an MOCVD section for forming a buffer layer 3, an undoped GaN layer 4, an n-type contact layer 5, a multilayer 6, a light emitting layer 7 with a multi-quantum well structure; an electric block layer 8; and a p-type contact layer 9 sequentially in this order by the MOCVD method; a transparent electrode forming section for forming a translucent thin film electrode 10 on the p-type contact layer 9; an n-electrode and p-electrode forming section for etching to remove an edge part of the substrate to a part of the n-type contact layer 5 to expose an edge part of the contact layer 5 to form an n-electrode 12 on the edge part surface of the n-type contact layer 5, and to form a p-electrode 11 on a part of a surface of the translucent thin film electrode 10; a protective layer forming section for forming a protective layer 13 on exposed surfaces of the translucent thin film electrode 10, p-electrode 11, n-electrode 12, n-type contact layer 5, and further on a side surface etched for removal for moisture-proofing; an electrode opening section for opening each of the protective layers 13 on the p-electrode 11 and the n-electrode 12; a capacitance measuring section for measuring the capacitance between the n-electrode 12 and the p-electrode 11; an impurity concentration distribution computing section for computing the impurity concentration distribution from the measured capacitance; a first impurity concentration distribution controlling section for controlling the minimum value of the impurity concentration distribution by controlling the MOCVD section so that maximum light emitting output can be obtained at the time of the next light emitting layer formation by comparing a standard value to the lowest value of the computed impurity concentration distribution as a characterizing amount; a light emitting output and drive voltage inspecting section for measuring light emitting output and drive voltage to inspecting whether they are good or bad; and a second impurity concentration distribution controlling section for controlling the impurity concentration distribution by controlling the MOCVD method so as to minimize the increase in drive voltage while obtaining the maximum light emitting output in accordance with the measured light emitting output and drive voltage at the next light emitting layer formation when the measured light emitting output and drive voltage exceeds a predetermined range.

In other words, the characterizing configuration of the method of manufacture of the nitride semiconductor light emitting element 1 of Embodiment 1 further comprises: a capacitance measuring step, wherein, after the formation of the p-type electrode 11 and the n-type electrode 12, the capacitance measuring section measures the capacitance between the p-type electrode 11 and the n-type electrode 12; the impurity concentration distribution computing step, wherein the impurity concentration distribution computing section computes the impurity concentration distribution from the measured capacitance; and the first impurity concentration distribution controlling step, wherein the first impurity concentration distribution controlling section controls the minimum value of the impurity concentration distribution by controlling the MOCVD section so that the maximum light emitting output can be obtained at the time of the light emitting layer formation in the next lot or substrate by comparing a standard value to the lowest value of the computed impurity concentration distribution as a characterizing amount. In addition, the characterizing configuration of the method of manufacture of the nitride semiconductor light emitting element 1 further comprises: the light emitting output and drive voltage inspecting step, wherein the light emitting output and drive voltage inspecting section measures the light emitting output and drive voltage for inspection; and the second impurity concentration distribution controlling step, wherein the second impurity concentration distribution controlling section controls the impurity concentration distribution by controlling the MOCVD method so as to minimize the increase of drive voltage while obtaining the maximum light emitting output in accordance with the measured light emitting output and drive voltage.

In comparison, the characterizing configuration of the manufacturing system of the nitride semiconductor light emitting element 1 of Embodiment 1 further comprises: the capacitance measuring section for measuring the capacitance between the n-electrode 12 and the p-electrode 11; the impurity concentration distribution computing section for computing the impurity concentration distribution from the measured capacitance; and the first impurity concentration distribution controlling section for controlling the minimum value of the impurity concentration distribution by controlling the MOCVD section so that the maximum light emitting output can be obtained at the time of the light emitting layer formation of the next lot or substrate by comparing a standard value to the lowest value of the computed impurity concentration distribution as a characterizing amount. In addition, the manufacturing system of the nitride semiconductor light emitting element 1 further comprises: the light emitting output and drive voltage inspecting section for measuring the light emitting output and drive voltage of the nitride semiconductor light emitting element 1 for inspection; and the second impurity concentration distribution controlling section for controlling the impurity concentration distribution by controlling the MOCVD method so as to minimize the increase of drive voltage while obtaining the maximum light emitting output in accordance with the measured light emitting output and drive voltage at the light emitting layer formation of the next lot or substrate when the measured light emitting output and drive voltage exceeds a predetermined range (good/bad range). This impurity concentration distribution is a distribution of n-type impurity concentration distribution, and the impurity is Si. For an n-type impurity, other than silicon (Si), there are selenium and tellurium.

The impurity concentration distribution specific to the substrate or the lot computed from the capacitance obtained in the capacitance measuring step of step S8 is fed back at the time of formation of the light emitting layer 7 in the MOCVD step of step S3, and in the MOCVD step of step S3, at the time of forming the light emitting layer 7, the amount of Si doped in the light emitting layer 7 is controlled so that the light output value is maximized in the range where the minimum value of the impurity concentration in the impurity concentration distribution in the direction of depth is present, in the characteristic curve (FIG. 2) where the impurity concentration distribution in accordance with the direction of depth which is calculated from the fed-back value of capacitance is a parameter. In other words, when the next light emitting layer 7 is formed in the MOCVD step, the impurity concentration distribution calculated from the measured capacitance value is fed back, and the amount of silicon (Si) doped in the light emitting layer 7 can be changed to an appropriate concentration.

In other words, capacitance is obtained in the capacitance measuring step of step S8, the impurity concentration distribution characteristic of FIG. 2 is computed from capacitance, and the supplied gas flow amount is controlled in the MOCVD method of step S3 so that the impurity concentration is in the range of 5×10¹⁶ to 9×10¹⁶(cm⁻³), or preferably the impurity concentration is 7×10¹⁶ (cm⁻³) as in measurement results B and C, with the lowest value of the impurity concentration as a characterizing amount. Thereby, the amount of silicon (Si) doped in the light emitting layer 7 is changed to an appropriate Si concentration.

For example, when the impurity concentration is detected to be 2×10¹⁷ as the lowest value of impurity concentration as a characterizing amount, the supplied gas flow amount in the MOCVD step of step S3 is supplied to be restrained so that the impurity concentration is in the range of 5×10¹⁶ to 9×10¹⁶(cm⁻³). Further, in contrast, when the impurity concentration is detected to be 2×10¹⁶ as the lowest value of impurity concentration as a characterizing amount, the supplied gas flow amount in the MOCVD step of step S3 is supplied to be increased so that impurity concentration is in the range of 5×10¹⁶ to 9×10¹⁶(cm⁻³).

In other words, in the manufacturing steps of the nitride semiconductor light emitting element 1 comprising a first step of forming a nitride semiconductor light emitting element structure on the sapphire substrate 2 by metal organic chemical vapor deposition, a second step for forming the p-electrode 11 and the n-electrode 12, and a third step for measuring the reverse current value as a reverse electric characteristic, the method of manufacture of the nitride semiconductor light emitting element 1 of Embodiment 1 uses the impurity concentration distribution corresponding to the direction of depth which is calculated from the capacitance value of the nitride semiconductor light emitting element 1 measured in the third step to select the minimum value of impurity concentration in the impurity concentration distribution of the measured result thereof, and control the Si concentration of n-conductive type impurity of the first step to the maximum Si concentration that does not lower light emitting output based on the selected impurity concentration.

In this case, the control of Si concentration of n-conductive type impurity is performed by controlling the SiH₄ gas flow amount or/and at least one of the SiH(CH₃)₃ gas flow amount and time of introduction. It is intended to restrain the increase in drive voltage to a minimum and maintain and improve the light emitting output by controlling the average concentration of n-conductive type impurity, by intermittently controlling the gas flow amount and gas introduction time of a metal organic chemical vapor deposition apparatus (MOCVD section) to an n-type impurity concentration that inhibits excessive Si doping, which becomes a cause of decrease in light emitting output, and restrains the increase of drive voltage due to an increase in resistance from the decrease in Si concentration.

The capacitance measured in the capacitance measuring step is a value measured by superimposing and applying at least one type of direct voltage and alternating voltage between the p-type electrode 11 and the n-type electrode 12, or a value measured by superimposing and applying at least one type of pulse voltage and alternating voltage between the p-type electrode 11 and the n-type electrode 12. The frequency of the alternating voltage is 100 kHz to 10 MHz. When measuring the capacitance, at higher frequencies, the impedance appears larger and the capacitance can be measured more accurately. Thus, the frequency thereof is set to be greater than or equal to 100 kHz, and here, the capacitance is measured with the frequency at 1 MHz. From the relationship of the recombination rate of an electron and a hole, if the frequency exceeds 10 MHz, the capacitance cannot be measured accurately in the contrary. The amplitude of the alternating voltage is to be in a range of amplitudes where neighboring information does not overlap or is disconnected, and is 5 mV to 30 mV in an experiment. Direct voltage is in the range of 0.8V to 2.8V with a forward bias with the p-electrode 11 as positive. The nitride semiconductor light emitting element 1 that emits blue based light starts to emit light from about 2.5V in an experiment. Since it is important to measure capacitance while the depletion layer is stretched in the stage prior to when the depletion layer starts emitting light, it is preferable that the capacitance is measured with direct voltage in the range of 0.8V to 2.8V, with p-electrode 11 as positive.

From the above, according to Embodiment 1, in the nitride semiconductor light emitting element comprising a light emitting layer 7 with a multi-quantum well structure on a monocrystalline substrate, the multilayer 6 alternately laminated with a plurality of first layers constituted of InₓGa₁₋ₓN (0<x<0.3) and second layers constituted of GaN on the n-electrode 12 side of the light emitting layer 7 is comprised, and the well layer of the light emitting layer 7 with a multi-quantum well structure is formed with In_{y}Ga_{1-y}N (0≦y<0.3) comprising at least In, and the light emitting output can be further improved without increasing the drive voltage by adding n-conductive type impurity in the range of 5×10¹⁶ cm⁻³ to 5×10¹⁸ cm⁻³ as the concentration thereof to at least the barrier layer of the light emitting layer 7 and adding n-conductive type impurity Si so that the minimum value of impurity concentration distribution of the light emitting layer 7 calculated from the measured result of capacitance value of the light emitting layer 7 is controlled. In this manner, since the feedback is controlled so that the maximum light emitting output can be obtained, with the lowest value of impurity concentration of the impurity concentration distribution computed from a measured capacitance as a characterizing amount, manufacturing variation (production fluctuation) of designed doping concentration and the concentration distribution in the direction of depth can be inhibited and the light emitting output can be improved and stabilized.

In Embodiment 1, controlling is performed by adding n-conductive type impurity in the range of 5×10¹⁶ cm⁻³ to 5×10¹⁸ cm⁻³ as the concentration thereof to at least the barrier layer of the light emitting layer 7, and using the minimum value of impurity concentration of the light emitting layer 7, and as an example thereof, based on an impurity concentration characteristic curve of the light emitting layer calculated from the measurement result of the capacitance measuring step, the minimum value thereof is controlled to the Si concentration at which light emitting output is at the maximum. A case where n-conductive type impurity Si is added to at least the barrier layer of the light emitting layer 7 has been described, but is not limited to this. N-conductive type impurity Si may be added to at least the barrier layer of the light emitting layer 7 at Si concentration in a predetermined range, where the minimum value of impurity concentration distribution calculated from the measurement result in the capacitance measuring step is in the back and front of where light emitting strength is at maximum. In other words, it is sufficient if n-conductive type impurity is added in the range of 5×10¹⁶ cm⁻³ to 5×10¹⁸ cm⁻³ as concentration thereof to at least the barrier layer of the light emitting layer 7.

In this case, in Embodiment 1, the Si concentration of at least a barrier layer of the light emitting layer 7 has been controlled, but is not limited to this. Si concentration of each of at least the barrier layer and the second layer of the light emitting layer 7 may be controlled. In other words, it is sufficient to control the average Si concentration of at least the barrier layer of the light emitting layer 7. Further, it goes without saying that at the time of forming the first layer of the light emitting layer 7, SiH₄ or SiH(CH₃)₃ gas may be introduced intermittently to control Si concentration as the first layer overall average. In this case, the parameter controlled is the time of gas introduction, not the gas flow amount.

In Embodiment 1, a method has been explained, wherein the alternating voltage and direction voltage of the light emitting layer 7 are superimposed, with the reverse current value as the reverse electric characteristic of a predetermined item as a parameter, the impurity concentration calculated from the measured capacitance obtained from the imaginary part of an obtained impedance and a characteristic curve showing the relationship between the light emitting output and the drive voltage are found beforehand, and the Si concentration of at least the barrier layer of the light emitting layer 7 is controlled based on a characteristic curve using a minimum value of impurity concentration distribution found in the capacitance measuring step as a parameter. However, a capacitance measuring method is not limited to the above-described reverse current value. It goes without saying that it may be a capacitance value calculated from a time constant of the transient current that is measured when a pulse voltage is applied.

In Embodiment 1, a case has been explained where, the capacitance is obtained in the capacitance measuring step of step S8 for each startup of an MOCVD device (or for each lot or substrate); impurity concentration distribution of FIG. 2 is computed from the capacitance; in the next MOCVD step, a standard value is compared to a lowest value of the impurity concentration as a characterizing amount; and at least one of the supplied gas flow amount and the gas introduction time in the MOCVD step of step S3 is controlled such that the minimum value of the impurity concentration distribution is in the range of 5×10¹⁶ to 9×10¹⁶(cm⁻³), but is not limited to this. It may be such that the nitride semiconductor light emitting element 1 is manufactured beforehand as a sample; the capacitance is obtained for the manufactured nitride semiconductor light emitting element 1 in the capacitance measuring step of step S8; the impurity concentration distribution characteristic corresponding to depth of FIG. 2 is computed from the measured capacitance; a table is made beforehand, which shows how much to increase or decrease the doping amount of impurity in order to set a characteristic value within a target range (within a standard range) with at least one of the actual supplied gas flow amount and the gas introduction time in the MOCVD step held at the characteristic value, with the minimum value of the impurity concentration distribution characteristic as the characteristic value; and by referring to at least one of the supplied gas flow amount and the gas introduction time of the table corresponding to the minimum value of the calculated impurity concentration distribution characteristic, at least one of the supplied gas flow amount and the gas introduction time in the MOCVD step of step S3 is controlled so that the impurity concentration is within the range of 5×10¹⁶ to 9×10¹⁶(cm⁻³).

In Embodiment 1, the lowest value of the computed impurity concentration distribution as a characterizing amount is compared to a standard value to control the minimum value of impurity concentration distribution. Although not specifically described herein, a hole and an electron combine when the computed impurity concentration distribution is at its lowest to emit the most light. Controlling is performed such that lowest impurity concentration of impurity concentration distribution is in the range of predetermined values (standard value) based on the lowest value of the impurity concentration.

In Embodiment 1, although not specifically described, in the first impurity concentration distribution controlling step, with the lowest value of the computed impurity concentration distribution as a characterizing amount, the flow amount and/or gas introduction time of SiH₄ gas and/or SiH(CH₃)₃ gas is controlled at the time of film growth of at least the barrier layer of the well layer and the barrier layer of the light emitting layer 7 in accordance with the characterizing amount. Light emitting output increases more when additionally doping Si in the barrier layer in comparison to additionally doping Si in the well layer.

In Embodiment 1, although not specifically described, in a nitride semiconductor light emitting element 1 manufactured by the method of manufacture of the above-described nitride semiconductor light emitting element 1, a characterizing amount is in the range of 5×10¹⁶ cm⁻³ to 9×10¹⁶ cm⁻³, with the lowest value of single conductive type (here, n-type) impurity concentration distribution in at least the barrier layer of the well layer and the barrier layer of the light emitting layer 7 as the characterizing amount. Preferably, a characterizing amount is within a range of tolerance of 7×10¹⁶ cm⁻³, with the lowest value of single conductive type (here, n-type) impurity concentration distribution as the characterizing amount.

In Embodiment 1, a case is described, where a semiconductor light emitting element, a method of manufacture thereof, and a manufacturing system of a semiconductor light emitting element of the present invention are applied to Embodiment 1 of a nitride semiconductor light emitting element, a method of manufacture thereof, and a manufacturing system of a nitride semiconductor light emitting element. However, other than the nitride compound semiconductor light emitting element of green, blue, and ultraviolet regions, the present invention can be applied to a semiconductor light emitting element such as a gallium/arsenic-based semiconductor light emitting element or indium/phosphorous-based semiconductor light emitting element.

As described above, the present invention is exemplified by the use of its preferred Embodiment 1. However, the present invention should not be interpreted solely based on Embodiment 1 described above. It is understood that the scope of the present invention should be interpreted solely based on the scope of the claims. It is also understood that those skilled in the art can implement equivalent scope of technology, based on the description of the present invention and common knowledge from the description of the detailed preferred Embodiment 1 of the present invention. Furthermore, it is understood that any patent, any patent application and any references cited in the present specification should be incorporated by reference in the present specification in the same manner as the contents are specifically described therein.

### INDUSTRIAL APPLICABILITY

The present invention can be applied in the field of a semiconductor light emitting element such as a nitride compound semiconductor light emitting element of a green, blue, or ultraviolet region and a method of manufacture thereof, and a manufacture system of a semiconductor light emitting element used in the method of manufacture of this semiconductor light emitting element, a multilayer 6 alternately laminated with first layers constituted of InₓGa₁₋ₓN (0<x<0.3) and second layers constituted of GaN on the n-electrode side 12 of the light emitting layer is comprised, and light emitting output can be maintained and improved without worsening drive voltage, as the impurity concentration of light emitting layer 7 is controlled by adding impurity to the light emitting layer 7 such that the impurity concentration is in the range of 5×10¹⁶ cm⁻³ to 5×10¹⁸ cm⁻³ and using a characteristic curve with the minimum value of the impurity concentration distribution of the light emitting layer 7 as the parameter.

Various other modifications will be apparent to and can be readily made by those skilled in the art without departing from the scope and spirit of this invention. Accordingly, it is not intended that the scope of the claims appended hereto be limited to the description as set forth herein, but rather that the claims be broadly construed.

What is claimed is:

1. A method of manufacture of a semiconductor light emitting element for forming a light emitting layer with a multi-quantum well structure on a monocrystalline substrate by an MOCVD section and for forming a p-type electrode and an n-type electrode to supply a current to the light emitting layer, comprising:
a capacitance measuring step, where, after the formation of the p-type electrode and the n-type electrode, a capacitance measuring section measures the capacitance between the p-type electrode and the n-type electrode;
an impurity concentration distribution computing step, where an impurity concentration distribution computing section computes an impurity concentration distribution of the light emitting layer from measured capacitance; and
a first impurity concentration distribution controlling step, where a first impurity concentration distribution controlling section controls impurity concentration so that maximum light emitting output can be obtained at a time of formation of the next light emitting layer, with a lowest value of impurity concentration of a computed impurity concentration distribution as a characterizing amount.

2. A method of manufacture of a semiconductor light emitting element according to claim 1, wherein the first impurity concentration distribution controlling step controls an impurity concentration distribution in at least a barrier layer of a well layer and the barrier layer of the light emitting layer.

3. A method of manufacture of a semiconductor light emitting element according to claim 1, wherein the first impurity concentration distribution controlling step controls so that a single conductive type impurity concentration distribution is in a range of 5×10¹⁶ cm⁻³ to 9×10¹⁶ cm⁻³, with a lowest value thereof as a characterizing amount.

4. A method of manufacture of a semiconductor light emitting element according to claim 1, wherein the first impurity concentration distribution controlling step controls so that a single conductive type impurity concentration distribution is at 7×10¹⁶ cm⁻³, with a lowest value thereof as a characterizing amount.

5. A method of manufacture of a semiconductor light emitting element according to claim 1, wherein the first impurity concentration distribution controlling step controls a minimum value of the impurity concentration distribution by controlling a flow amount of SiH₄ gas and/or SiH(CH₃)₃ gas at a time of growth of at least a barrier layer of a well layer and the barrier layer of the light emitting layer.

6. A method of manufacture of a semiconductor light emitting element according to claim 1, wherein the first impurity concentration distribution controlling step controls a minimum value of the impurity concentration distribution by controlling an introduction time of SiH₄ gas and/or SiH(CH₃)₃ gas at a time of growth of at least a barrier layer of a well layer and the barrier layer of the light emitting layer.

7. A method of manufacture of a semiconductor light emitting element according to claim 1, wherein the capacitance measured in the capacitance measuring step is a value that is measured by superimposing and applying at least one type of direct voltage and alternating voltage between the p-type electrode and the n-type electrode.

8. A method of manufacture of a semiconductor light emitting element according to claim 1, wherein the capacitance measured in the capacitance measuring step is a value that is measured by superimposing and applying at least one type of pulse voltage and alternating voltage between the p-type electrode and the n-type electrode.

9. A method of manufacture of a semiconductor light emitting element according to claim 7, wherein a frequency of the alternating voltage is 100 kHz to 10 MHz.

10. A method of manufacture of a semiconductor light emitting element according to claim 8, wherein a frequency of the alternating voltage is 100 kHz to 10 MHz.

11. A method of manufacture of a semiconductor light emitting element according to claim 7, wherein an amplitude of the alternating voltage is 5 mV to 30 mV.

12. A method of manufacture of a semiconductor light emitting element according to claim 8, wherein an amplitude of the alternating voltage is 5 mV to 30 mV.

13. A method of manufacture of a semiconductor light emitting element according to claim 7, wherein the direct voltage is in a range of 0.8V to 2.8V, with the p-electrode as positive.

14. A method of manufacture of a semiconductor light emitting element according to claim 1, wherein the impurity concentration distribution is an n-type impurity concentration distribution, and the impurity is Si.

15. A method of manufacture of a semiconductor light emitting element according to claim 1, wherein a multilayer alternately laminated with a first layer constituted of InₓGa₁₋ₓN (0<x<0.3) and a second layer constituted of GaN is formed on the n-electrode side of the light emitting layer with the multi-quantum well structure on the monocrystalline substrate by the MOCVD method, and as the light emitting layer, a well layer constituted of In_{y}Ga_{1-y}N (0<y<0.3) comprising at least In and a barrier layer constituted of In_{y}Al_{z}Ga_{1-y-z}N (0≦y<0.1, 0≦z<0.2) are formed.

16. A method of manufacture of a semiconductor light emitting element according to claim 15, wherein impurity is added at a single conductive type impurity concentration in a range of 5×10¹⁶ cm⁻³ to 5×10¹⁸ cm⁻³, to at least a barrier layer of the light emitting layer.

17. A method of manufacture of a semiconductor light emitting element according to claim 1, further comprising:
a light emitting output and drive voltage inspecting step, wherein a light emitting output and drive voltage inspecting section measures light emitting output and drive voltage for inspection; and
a second impurity concentration distribution controlling step, where a second impurity concentration distribution controlling section controls the impurity concentration distribution of the light emitting layer by controlling the MOCVD section so as to minimize an increase of the drive voltage while obtaining maximum light emitting output in accordance with the measured light emitting output and drive voltage at a time of formation of a next light emitting layer, when at least one of the measured light emitting layer and the drive voltage exceeds a predetermined range.

18. A semiconductor light emitting element manufactured by the method of manufacture of a semiconductor light emitting element according to claims 1, wherein a lowest value of a single conductive type impurity concentration distribution in at least a barrier layer of a well layer and the barrier layer of the light emitting layer is in a range of 5×10¹⁶ cm⁻³ to 9×10¹⁶ cm⁻³.

19. A semiconductor light emitting element according to claim 18, wherein the lowest value of the single conductive type impurity concentration distribution is at a tolerance of 7×10¹⁶ cm⁻³.

20. A manufacturing system of a semiconductor light emitting element for forming a light emitting layer with a multi-quantum well structure on a monocrystalline substrate by an MOCVD section and for forming a p-type electrode and an n-type electrode to supply a current to the light emitting layer, comprising:
a capacitance measuring section for measuring the capacitance between the p-type electrode and the n-type electrode after the formation of the p-type electrode and the n-type electrode;
an impurity concentration distribution computing section for computing an impurity concentration distribution of the light emitting layer from measured capacitance; and
a first impurity concentration distribution controlling section for controlling so that maximum light emitting output can be obtained at a time of formation of the next light emitting layer, with a lowest value of impurity concentration of a computed impurity concentration distribution as a characterizing amount.

21. A manufacturing system of a semiconductor light emitting element according to claim 20, wherein the first impurity concentration distribution controlling section controls an impurity concentration distribution in at least a barrier layer of a well layer and the barrier layer of the light emitting layer.

22. A manufacturing system of a semiconductor light emitting element according to claim 20, wherein the first impurity concentration distribution controlling step controls so that a single conductive type impurity concentration distribution is in a range of 5×10¹⁶ cm⁻³ to 9×10¹⁶ cm⁻³, with a lowest value thereof as a characterizing amount.

23. A manufacturing system of a semiconductor light emitting element according to claim 20, wherein the first impurity concentration distribution controlling step controls so that a single conductive type impurity concentration distribution is at 7×10¹⁶ cm⁻³, with a lowest value thereof as a characterizing amount.

24. A manufacturing system of a semiconductor light emitting element according to claim 20, wherein the first impurity concentration distribution controlling step controls a minimum value of the impurity concentration distribution by controlling a flow amount of SiH₄ gas and/or SiH(CH₃)₃ gas at a time of growth of at least a barrier layer of a well layer and the barrier layer of the light emitting layer.

25. A manufacturing system of a semiconductor light emitting element according to claim 20, wherein the first impurity concentration distribution controlling step controls a minimum value of the impurity concentration distribution by controlling an introduction time of SiH₄ gas and/or SiH(CH₃)₃ gas at a time of growth of at least a barrier layer of a well layer and the barrier layer of the light emitting layer.

26. A manufacturing system of a semiconductor light emitting element according to claim 20, further comprising:
a light emitting output and drive voltage inspecting section for measuring the light emitting output and drive voltage for inspection; and
a second impurity concentration distribution controlling section for controlling the impurity concentration distribution of the light emitting layer by controlling the MOCVD section so as to minimize an increase of the drive voltage while obtaining maximum light emitting output in accordance with the measured light emitting output and drive voltage at a time of formation of a next light emitting layer, when at least one of the measured light emitting layer and the drive voltage exceeds a predetermined range.
